(19) United States
(12) Patent Application Publication
(10) Pub. No.: US 2020/0220024 A1
(43) Pub. Date: Jul. 9, 2020

(54) CHARGE TRAP LAYER IN BACK-GATED THIN-FILM TRANSISTORS

(71) Applicant: Intel Corporation, Santa Clara, CA (US)

(72) Inventors: Abhishek A. Sharma, Hillsboro, OR (US); Van H. Le, Portland, OR (US); Jack T. Kavalieros, Portland, OR (US); Cory E. Weber, Hillsboro, OR (US); Sean T. Ma, Portland, OR (US); Tahir Ghani, Portland, OR (US); Shriram Shivaraman, Hillsboro, OR (US); Gilbert Dewey, Beaverton, OR (US)

(73) Assignee: Intel Corporation, Santa Clara, CA (US)

(21) Appl. No.: 16/640,469

(22) PCT Filed: Sep. 29, 2017
(86) PCT No.: PCT/US17/54415

§ 371 Date: Feb. 20, 2020

(51) Int. Cl. H01L 29/786; H01L 29/16; H01L 29/51; H01L 29/792; H01L 27/108

(52) U.S. Cl. CPC H01L 29/78669; H01L 29/78678; H01L 29/78684; H01L 27/10814; H01L 29/517; H01L 29/792; H01L 29/1604

(57) ABSTRACT

A back-gated thin-film transistor (TFT) includes a gate electrode, a gate dielectric on the gate electrode, an active layer on the gate dielectric and having source and drain regions and a semiconductor region physically connecting the source and drain regions, a capping layer on the semiconductor region, and a charge trap layer on the capping layer. In an embodiment, a memory cell includes this back-gated TFT and a capacitor, the gate electrode being electrically connected to a wordline and the source region being electrically connected to a bitline, the capacitor having a first terminal electrically connected to the drain region, a second terminal, and a dielectric medium electrically separating the first and second terminals. In another embodiment, an embedded memory includes wordlines extending in a first direction, bitlines extending in a second direction crossing the first direction, and several such memory cells at crossing regions of the wordlines and bitlines.

### BACKGROUND

A thin-film transistor (TFT) is generally fabricated by depositing thin films of an active semiconductor layer as well as the dielectric layer and metallic contacts over a substrate. A back-gated TFT has its gate on a side of the device that is opposite to the side on which the source and drain regions are located. There are a number of non-trivial performance issues associated with back-gated TFTs.

### BRIEF DESCRIPTION OF THE DRAWINGS

FIG. 1 is a cross-sectional view of an example back-gated thin-film transistor (TFT) with charge trap layer, according to an embodiment of the present disclosure.

FIG. 2 is a cross-sectional view of an example embedded memory cell having a stacked capacitor with a back-gated TFT, according to an embodiment of the present disclosure.

FIG. 3 is a cross-sectional view of an example embedded memory cell having a U-shaped capacitor with a back-gated TFT, according to an embodiment of the present disclosure.

FIG. 4 is a cross-sectional view of an example embedded memory, according to an embodiment of the present disclosure.

FIG. 5 is an example voltage-current curve and comparison curve for driving a back-gated TFT, according to an embodiment of the present disclosure.

FIG. 6 is a schematic plan view of an example embedded memory configuration, according to an embodiment of the present disclosure.

FIG. 7A is a plan view of an example layout of an embedded memory without overlap of the memory array and memory peripheral circuit.

FIGS. 7B-7C are plan views of an example layout of an embedded memory with overlap of the memory array and memory peripheral circuit, according to an embodiment of the present disclosure.

FIG. 8 illustrates an example method of fabricating a back-gated TFT-based memory array, according to an embodiment of the present disclosure.

FIG. 9 illustrates an example computing system implemented with the integrated circuit structures or techniques disclosed herein, according to an embodiment of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. In short, the figures are provided merely to show example structures.

### DETAILED DESCRIPTION

According to various embodiments of the present disclosure, a back-gated thin-film transistor (TFT) has a charge trap layer at the top of the TFT. The back-gated TFT can be a TFT with a significant source-body voltage bias (e.g., significant enough to cause a body effect or back-gate effect). In some embodiments, the back-gated TFT has a bottom gate electrode, a gate dielectric (such as a non-conducting oxide layer) on the gate, a semiconductor layer (or body) on the oxide layer, source and drain electrodes on the body respectively corresponding to source and drain regions of the body, and a capping layer on the body and corresponding to the channel region of the body. In some embodiments, the charge trap layer is on the capping layer that covers and seals the body (e.g., above the channel region). The capping layer can form a good interface with the body materials, helping to prevent leakage and being hermetic to other metal layers or features.

While the capping layer is supposed to help prevent leakage, in some circumstances, the capping layer can actually create leakage (such as through the capping layer or through the capping layer-channel boundary due to, for instance, unintended doping of the channel region-capping layer area resulting from the forming of the capping layer). For example, when the drain to source current is close to the surface (e.g., at or near the capping layer-channel region interface), the current can be prone to leaking through the capping layer. Accordingly, and in various embodiments of the present disclosure, the charge trap layer is located on top of the capping layer, to help lessen or prevent current leakage through the capping layer, For instance, when electrons are the majority carrier in the channel region (such as for n-type semiconductor material), the charge trap layer can have a negative charge, while when holes are the majority carrier in the channel region (such as for p-type semiconductor material), the charge trap layer can have a positive charge. The charge trap layer can improve short-channel effects in the TFT. The charge trap layer can deplete the capping layer and provide a constant negative body bias which makes the TFT depleted on the top surface and makes it resilient to leakage through the capping layer.

### General Overview

As noted above, there are a number of non-trivial performance issues associated with back-gated thin-film transistors (TFTs). In back-gated thin-film transistors (TFTs), thick channel material may be needed in the semiconductor bodies because of factors such as the source and drain contact etching having little to no selectivity (which can cause problems with thin channel regions). TFTs with thick bodies do not show good electrostatic gate control. Further, thick bodies can cause subthreshold swing (SS) degradation and high-voltage devices. Passivation layers on top of the TFTs cause interactions that can lead to undesirable doping, which can cause problems such as increased off-state leakage and degraded SS.

Thus, according to some embodiments, a back-gated thin-film transistor (TFT, such as a bottom-gate TFT) is provided that has a charge trap layer added to the top of a passivation layer of the back-gated TFT. The passivation layer covers a channel region of the TFT. The charge trap layer can store a negative charge Q_{SS} (such as for n-type semiconductor channels; positive charges can be used similarly for p-type channels). In some embodiments, the negative charge Q_{SS} reduces or prevents any SS degradation due to the passivation layer. This improves SS and helps offset the thick-body effect in such TFTs. For example, in some embodiments, the charge trap layer is an oxide or nitride layer (possibly in combination with other materials) doped with impurities (e.g., negatively charged impurities to create a negative charge, or positively charged impurities to create a positive charge) to create vacancies in the structure (e.g., oxide or nitride structure). The charge trap layer retains the charge and directs the charge carriers in the channel region away from the capping layer (and closer to the gate dielectric), to help prevent current leakage through the capping layer and reduce SS degradation when driving the TFT.

In an example embodiment of the present disclosure, a back-gated thin-film transistor (TFT) includes a gate electrode, a gate dielectric on the gate electrode, an active layer on the gate dielectric and including source and drain regions and a semiconductor region physically connecting the source and drain regions, a capping layer on the semiconductor region, and a charge trap layer on the capping layer. The charge trap layer can include an insulator material, such as an oxide or nitride. The oxide or nitride can be formed (e.g., deposited) on the capping layer, and the formed oxide or nitride then doped with impurities to cause the doped oxide or nitride to trap charges of the appropriate polarity. For example, the doping of the oxide or nitride can include doping the charge trap layer with ions having the same polarity as majority carriers of the semiconductor layer that makes up the channel (semiconductor) region.

In another example embodiment, a memory cell (such as a dynamic random-access memory (DRAM) cell) includes this back-gated TFT and a capacitor. The gate electrode of the TFT is electrically connected to a wordline and the source region is electrically connected to a bitline. The capacitor includes a first terminal electrically connected to the drain region, a second terminal, and a dielectric medium electrically separating the first and second terminals. In yet another example embodiment, a memory array (such as a DRAM array or embedded DRAM (eDRAM) array) includes a plurality of wordlines extending in a first direction, a plurality of bitlines extending in a second direction crossing the first direction, and a plurality of such memory cells at crossing regions of the wordlines and the bitlines, with the wordline and bitline of each memory cell being corresponding ones of the wordlines and bitlines, respectively.

In accordance with some embodiments of the present disclosure, an eDRAM includes the above-described back-gated TFTs as backend TFTs, together with corresponding capacitors to form memory cell arrays, and wordlines and bitlines to access the memory cell arrays. Two different states (e.g., logical 1 or 0) of each capacitor can be sensed, for example, on a corresponding one of the bitlines. For instance, by selecting the memory cell (e.g., using a unique combination of bitline and wordline, as driven by control circuits such as a wordline driver), amplifying the bias (e.g., using a sense amplifier) imparted by the selected capacitor on the bitline, and comparing the amplified sensed bias to that of an unbiased bitline, the state of the capacitor (1 or 0) for the memory cell can be determined. Using backend TFTs, e.g., TFTs formed during a back end of line (BEOL) process, the front end of line (FEOL) process can be used to fabricate a frontend circuit, such as the memory controller (e.g., wordline drivers, sense amplifiers, and the like) logic underneath the memory array. This allows more room for the backend TFTs and capacitors, allowing them to continue to function as memory devices even with smaller process technologies, such as 14 nanometer (nm), 10 nm, 7 nm, 5 nm, and beyond.

### Architecture and Methodology

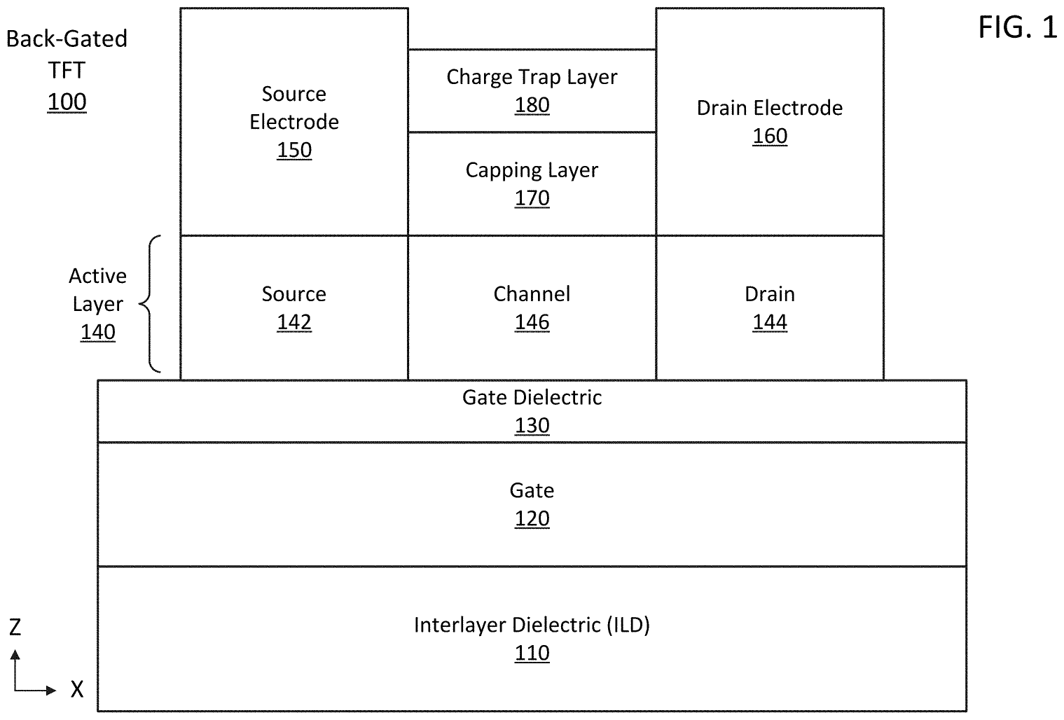

FIG. 1 is a cross-sectional (X-Z) view of an example back-gated thin-film transistor (TFT) 100 with charge trap layer 180, according to an embodiment of the present disclosure. Throughout, the z-axis represents a vertical dimension (e.g., perpendicular to an integrated circuit substrate), while the x- and y-axes represent horizontal dimensions (e.g., parallel to the wordline and bitline directions, respectively). The components of back-gated TFT 100 can be fabricated using semiconductor fabrication techniques, such as deposition and photolithography. The components of TFT 100 can be part of a backend process, such as the back end of line (BEOL) process of a semiconductor integrated circuit. As such, the components of back-gated TFT 100 can be fabricated as part of, or concurrently with, the metal interconnection layers (such as the upper or middle metal interconnection layers) of a semiconductor fabrication process. In some other embodiment, the components of back-gated TFT 100 are fabricated as part of a front end of line (FEOL) process (e.g., on a substrate instead of the ILD 110).

In example embodiments, fabrication of the components of TFT 100 can be part of the metal 4 (interconnect) layer of a BEOL process, using mostly a custom process (e.g., separate from the other metal 4 features) to form the components. Referring to FIG. 1, a gate (or gate electrode) 120 is formed, such as on an interlayer dielectric (ILD, such as an etch stop material) 110. The gate 120 is conductive, and can represent one or more layers or features for supplying a gate signal to the TFT 100. For instance, the gate 120 can include a wordline (such as a wordline made of copper (Cu) or aluminum (Al)) to supply a gate signal from a wordline driver, along with diffusion barriers and a metal gate electrode for supplying the gate signal to the proximity of the channel region of the TFT 100.

For example, the gate 120 can include thin-film layers such as one or more gate electrode layers (e.g., diffusion barrier and metal gate layers). The diffusion barrier can be a metal- or copper-diffusion barrier (e.g., a conductive material to reduce or prevent the diffusion of metal or copper from a wordline into the metal gate 120 while still maintaining an electrical connection between the wordline and the metal gate 120) on the wordline such as tantalum nitride (TaN), tantalum (Ta), titanium zirconium nitride (e.g., Ti_{X}Zr_{1-X}N, such as X=0.53), titanium nitride (e.g., TiN), titanium tungsten (TiW), combination (such as a stack structure of TaN on Ta), or the like.

For instance, the diffusion barrier can include a single- or multi-layer structure including a compound of tantalum(Ta) and nitrogen(N), such as TaN or a layer of TaN on a layer of Ta. In some embodiments, a layer of etch-resistant material (e.g., etch stop) such as silicon nitride (e.g., Si₃N₄) or silicon carbide (e.g., SiC) is formed over the wordline with vias for a metal (or copper) diffusion barrier film such as TaN or a TaN/Ta stack. The metal gate can be a conductive material on the diffusion barrier, such as metal, conductive metal oxide or nitride, or the like. For example, in one embodiment, the metal gate is titanium nitride (TiN). In another embodiment, the metal gate is tungsten (W).

The gate 120 is covered with a gate dielectric 130 corresponding to an active (semiconductor) layer 140 (or to a channel area 146 of the active layer) of the back-gated TFT 100. The gate dielectric 130 can be a high-κ dielectric material such as hafnium dioxide (HfO₂). The gate dielectric 130 can be thin, such as 4 nanometers (nm). In some embodiments, the gate dielectric 130 is in a range of 3 nm to 7 nm. In some embodiments, the gate dielectric 130 is in a range of 2 nm to 10 nm. In some embodiments, the gate dielectric 130 can be silicon dioxide (SiO₂), silicon nitride (e.g., Si₃N₄), hafnium dioxide (HfO₂) or other high-κ material, or a multi-layer stack including a first layer of SiO₂ and a second layer of a high-κ dielectric such as HfO₂ on the SiO₂. Any number of gate dielectrics can be used, as will be appreciated in light of the present disclosure. For example, in one embodiment, the gate dielectric 130 is a layer of SiO₂. In another embodiment, the gate dielectric 130 is a stack (e.g., two or more layers) of HfO₂ on SiO₂.

The semiconductive active layer 140 is formed over the gate dielectric 130, such as in direct contact with the gate dielectric 130. The active layer 140 can be formed in a backend process, for example, from one or more of indium gallium zinc oxide (IGZO), indium zinc oxide (IZO), amorphous silicon (a-Si), low-temperature polycrystalline silicon (LTPS), and amorphous germanium (a-Ge). For example, the active layer 140 can be IGZO or the like in contact with a bitline (such as at a source region 142 of the active layer 140) and a storage node (e.g., at a drain region 144 of the active layer 140), with a semi-conductive channel region 146 between and physically connecting the drain region 144 and the source region 142. Such an active layer channel 146 may include only majority carriers in the thin film. Accordingly, the active layer channel 146 may require high bias (as supplied by the wordline, diffusion barrier film, and metal gate) to activate. In addition to IGZO, in some embodiments, the active layer 140 is one of a variety of polycrystalline semiconductors, including, for example, zinc oxynitride (ZnON, such as a composite of zinc oxide (ZnO) and zinc nitride (Zn₃N₂), or of ZnO, ZnOₓN_{y}, and Zn₃N₂), indium tin oxide (ITO), tin oxide (e.g., SnO), copper oxide (e.g., Cu₂O), polycrystalline germanium (poly-Ge), silicon-germanium (e.g., SiGe, such as Si₁₋ₓGeₓ) structures (such as a stack of poly-Ge over SiGe), and the like.

In some embodiments, the active layer 140 is formed from first type channel material, which may be an n-type channel material or a p-type channel material. An n-type channel material may include indium tin oxide (ITO), indium gallium zinc oxide (IGZO), indium zinc oxide (IZO), aluminum-doped zinc oxide (AZO), amorphous silicon (a-Si), zinc oxide (e.g., ZnO), amorphous germanium (a-Ge), polycrystalline silicon (polysilicon or poly-Si), poly-germanium (poly-Ge), or poly-III-V like indium arsenide (InAs). On the other hand, a p-type channel material may include amorphous silicon, zinc oxide, amorphous germanium, polysilicon, poly germanium, poly-III-V like InAs, copper oxide (CuO), or tin oxide (SnO). The channel region 146 have a thickness in a range of about 10 nm to about 100 nm.

As mentioned, the active layer 140 can be divided into three different regions, namely the source and drain regions 142 and 144 with the channel region 146 between and physically connecting the source and drain regions 142 and 144. The active layer 140 forms a transistor device with the gate 120 and gate dielectric 130. When a gate signal is supplied to the gate 120, the active layer 140 becomes conductive, and current flows between the source and drain regions 142 and 144 via the channel region 146.

Above the active layer 140, a capping layer 170 is formed. between source and drain electrodes 150 and 160. The capping layer 170 is formed above the channel region 146. The capping layer 170 forms a good interface with the active layer 140 materials, preventing leakage and being hermetic to other metal layers or features. In some embodiments, the capping layer 170 physically connects and electrically separates the source and drain electrodes 150 and 160.

For example, in some embodiments, the capping layer includes an insulator material, such as aluminum oxide (e.g., Al₂O₃), gallium oxide (e.g., Ga₂O₃), silicon nitride (e.g., Si₃N₄, SiN), silicon dioxide (SiO₂), titanium dioxide (TiO₂), hafnium dioxide (HfO₂), silicon oxynitride (e.g., Si₂N₂O, SiOₓN_{y} with 0≤x≤2 and 0≤y≤4/3), aluminum silicate (e.g., Al₂O₃(SiO₂)ₓ with x>0), tantalum oxide (e.g., Ta₂O₅), hafnium tantalum oxide (e.g., HfTaₓO_{y} with x>0 and y>2), aluminum nitride (e.g., AlN), aluminum silicon nitride (e.g., AlSiₓN_{y} with x>0 and y>1), sialon (e.g., AlSixOyNz with x>0, y>0, and z>0), zirconium dioxide (ZrO₂), hafnium zirconium oxide (e.g., HfZrₓO_{y} with x>0 and y>2), tantalum silicate (e.g., TaSiₓO_{y} with x>0 and y>0), hafnium silicate (e.g., HfSiO₄, HfSiₓO_{y} with x>0 and y>2), or the like.

The source electrode 150 is formed and electrically connected to the source region 142 and the drain electrode 160 is formed and electrically connected to the drain region 144. The source and drain electrodes 150 and 160 can be metal, such as metal interconnect layer material (e.g., Cu, Al, or tungsten (W)). The TFT 100 acts as a switch, electrically connecting the source and drain electrodes 150 and 160 in response to a gate signal, such as a gate signal being supplied to the gate 120.

Above the capping layer 170, a charge trap layer 180 is formed. The charge trap layer 180 is for retaining a charge of the same polarity as the majority carriers of the active layer 140 (e.g., to direct current between the drain electrode 160 and the source electrode 150 away from the capping layer 170 and closer to the gate dielectric 130). To this end, the charge trap layer 180 can include an oxide or nitride, such as a doped oxide or nitride. The oxide or nitride can be any oxide or nitride capable of trapping such a charge (e.g., either doped or undoped), and in some embodiments, can include one or more of silicon nitride (e.g., Si₃N₄, SiN), tantalum oxide (e.g., Ta₂O₅, TaO₂), titanium oxide (e.g., TiO₂, TiOₓ with 0<x<2), silicon oxynitride (e.g., Si₂N₂O, SiOₓN_{y} with 0≤x≤2 and 0≤y≤4/3), hafnium dioxide (HfO₂), hafnium titanium oxide (e.g., HfTiO4, HifixOy with x>0 and y>2), hafnium tantalum oxide (e.g., HfTaₓO_{y} with x>0 and y>2), aluminum nitride (e.g., AlN), aluminum oxynitride (e.g., (AlN)ₓ(Al₂O₃)₁₋ₓ with 0.30≤x 0.37)), silicon aluminum nitride (e.g., Si(AlN)ₓ with x>0, SiAlₓN_{y} with x>0 and y>0), silicon:silicon dioxide (e.g., Siₓ(SiO₂)₁₋ₓ with 0<x<1), silicon:hafnium dioxide (e.g., Siₓ(HfO₂)₁₋ₓ with 0<x<1), silicon:silicon nitride (e.g., Siₓ(SiN)₁₋ₓ with 0<x<1), gallium oxide (e.g., Ga₂O₃), and aluminum oxide (e.g., Al₂O₃). In some embodiments, the charge trap layer 180 physically connects and electrically separates the source and drain electrodes 150 and 160.

For example, the oxide or nitride can be formed on the capping layer 170 and doped with appropriate impurities (e.g., n-type impurities for electrons as majority carriers in the channel region 146 or p-type impurities for holes as the majority carriers). The doped impurities can create vacancies (e.g., oxygen or nitrogen) in the oxide or nitride structure and trap charges of the appropriate polarity. The charge trap layer 180 can be charged, for example, by driving sufficient positive or negative voltage (as appropriate for the majority carrier in the channel region 146) in the source or drain electrodes 150 and 160 (e.g., periodically, during power-on, or the like). After charging, the charge trap layer 180 retains the charge during normal operations and functions to bias the current flow between the drain region 144 and the source region 142 away from the boundary of the capping layer 170 and the channel region 146.

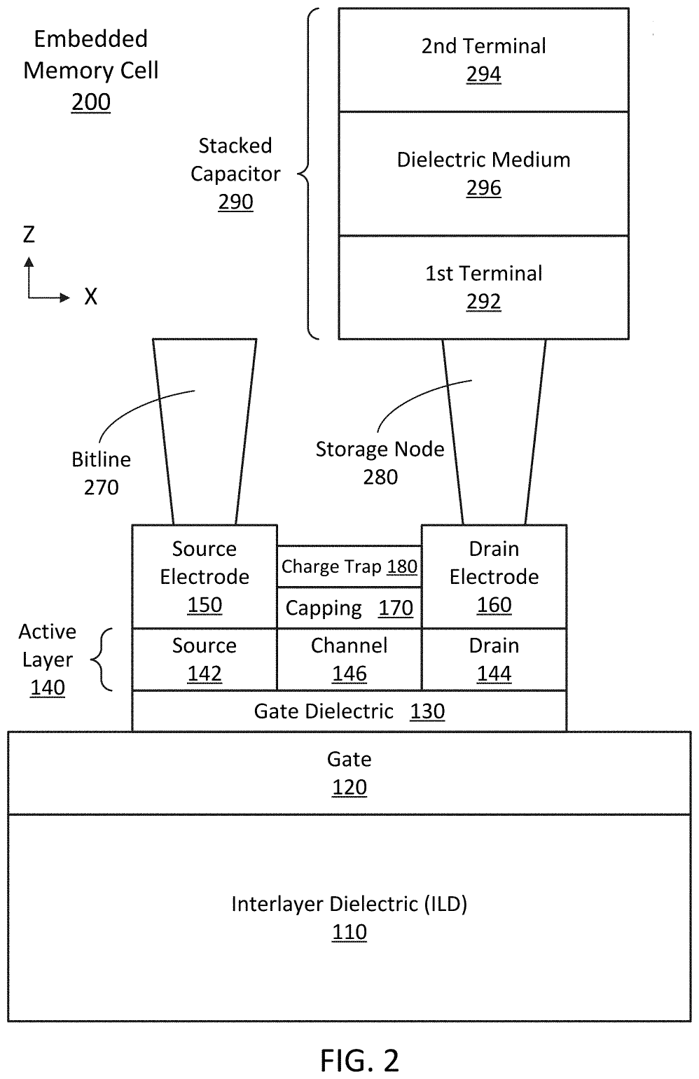

FIG. 2 is a cross-sectional (X-Z) view of an example embedded memory cell 200 having a stacked capacitor 290 with a back-gated TFT (such as the back-gated TFT 100 of FIG. 1), according to an embodiment of the present disclosure. In FIG. 2, a metal bitline 270 (e.g., metal interconnect material, such as copper, aluminum, or tungsten) is formed on the source electrode 150. The bitline 270 is used, for example, to program or sense the capacitance of the capacitor 290 through the source region 142 of the back-gated TFT 100 when the TFT 100 is turned on. In addition, a storage node 280 (e.g., further metal interconnect material) is formed on the drain electrode 160. The storage node 280 electrically connects the drain electrode 160 to the capacitor 290 to write (e.g., program) or read (e.g., sense) the capacitance (e.g., logical 1 or 0) of the capacitor 290 (e.g., through the bitline 270 when the TFT 100 is turned on).

In some embodiments, the bitline 270 is used in combination with the storage node 280 to sense the state of a capacitor when the TFT 100 is used as part of a memory device (such as a DRAM cell). In some other embodiments, the TFT 100 acts as a switch, controlling an electrical current between the storage node 280 and bitline 270. In some embodiments, the roles of the source and drain electrodes 150 and 160 are reversed, the drain electrode 160 being connected to the bitline 270 and the source electrode 150 being connected to the storage node 280.

The stacked capacitor 290 is formed in layers (e.g., as part of a BEOL process, such as part of the metal 6 interconnect layer). The capacitor 290 includes a first terminal 292, a dielectric (or dielectric medium) 296 on the first terminal 292, and a second terminal 294 on the on the dielectric 296. The first and second terminals 292 and 294 can be metals or other conductive materials (e.g., metal, conductive metal nitride or carbide, or the like), while the dielectric 296 can be an insulator to electrically separate the first and second terminals 292 and 294, allowing a capacitance to be formed between the first and second terminals 292 and 294. The first terminal 292 is electrically connected to the drain electrode 160 via the storage node 280. The second terminal 294 can be electrically connected, for example, to a common or programmable voltage (such as a ground voltage), or to a plate line (e.g., to all the memory cells 200 sharing the same wordline driving the gate 120) for supplying a common or programmable voltage.

In further detail, in one embodiment, the first terminal 292 is tantalum (Ta). In another embodiment, the first terminal 292 is titanium nitride (TiN). In some embodiments, the first terminal 292 is titanium aluminum nitride (e.g., TiAlN, where the molar amount of titanium is at least that of aluminum). In another embodiment, the first terminal 292 is tantalum aluminum carbide (TaAlC). In another embodiment, the first terminal 292 is tantalum nitride (TaN). For example, in one embodiment, the second terminal 292 is TiN. For example, in one embodiment, the dielectric 296 is SiO₂. In some embodiments, such as to reduce tunneling (e.g., when the dielectric 296 is very thin), the dielectric 296 is a high-κ dielectric material such as zirconium dioxide (ZrO₂) or aluminum oxide (Al₂O₃).

The first terminal 292 of the capacitor 290 connects to a corresponding storage node 280 through the storage node 280. The first terminals 292 of multiple such capacitors 290 (e.g., belonging to memory cells coupled to the same wordline) are electrically insulated from each other while the second terminal 294 of the capacitors 290 are electrically connected to each other through a (shared) capacitor plate or plate line at the top of the capacitors 290 (e.g., located in the via portion of the metal 7 interconnect layer). There may be separate capacitor plates for separate arrays of capacitors 290 (e.g., one for each wordline). The capacitor plates may be coupled to a common voltage line (for example, in the interconnect portion of the metal 7 layer) to supply a common voltage to all the second terminals 294 through the capacitor plate.

The source contact of the TFT 100 is continuous and is used as the bitline 270 of the memory cell 200. The heights of the source and drain contacts can be optimized to reduce bitline capacitance (e.g., between the source and drain contacts) for better sensing margins. The source contacts of the TFTs 100 also serve as the bitlines of an embedded memory array. The dimensions of the source contacts (bitlines 270) can be customized for lower inter-metal capacitance (e.g., by using a separate fabrication stage to form the bitlines 270 versus the fabrication stage for this metal level in areas of the integrated circuit outside of the memory array). Each capacitor 290 connects to a drain contact (e.g., storage node 280) of the TFT 100.

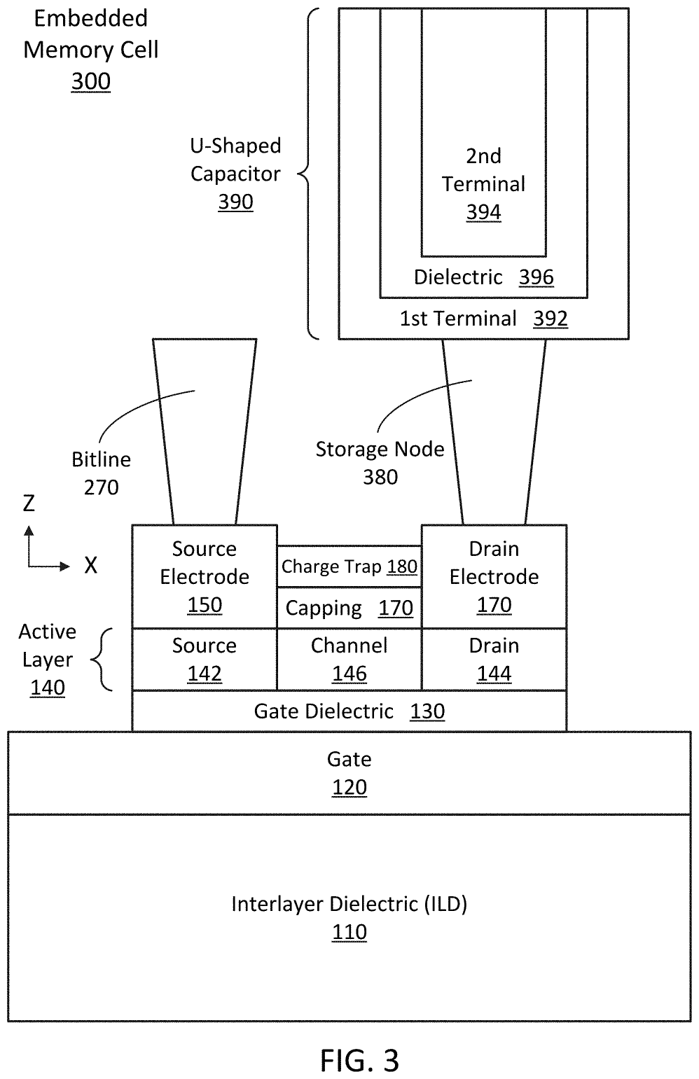

FIG. 3 is a cross-sectional (X-Z) view of an example embedded memory cell 300 having a U-shaped capacitor 390 with a back-gated TFT (such as the back-gated TFT 100 of FIG. 1), according to an embodiment of the present disclosure. Here, the embedded memory cell 300 has a similar structure to that of the embedded memory cell 200 in FIG. 2, but the capacitor 390 has a U-shaped structure, with first and second terminals 392 and 394, and a U-shaped dielectric 396. The U-shape can take advantage of the thicker metal interconnection layers to etch a relatively deep trench to boost capacitive surface area and capacitance without increasing planar area. Some of the components are the same or similar between the embodiments of FIGS. 2-3, and are numbered the same. For ease of discussion, their descriptions may not be repeated. Further, the materials for similarly numbered or named structures can be substantially the same between the two embodiments.

In an array of such embedded memory cells 300, storage nodes 380 (drain contacts) of the back-gated TFTs 100 in the memory cells 300 are separated between cells 300. Each storage node 380 is connected to a U-shaped capacitor 390, such as a metal-insulator-metal (MIM) capacitor above. For example, the storage node may be one or more structures electrically connecting the drain electrode 160 to the first terminal 392 through one or more BEOL layers, such as the metal 5 interconnect and metal 6 via portions of the backend processing. The capacitor 390 may be fabricated in the interconnect portion of the metal 6 layer and the via portion of the metal 7 layer. The capacitor 390 may be fabricated by etching (for example, by photolithography) deep, narrow trenches in the upper portion of the metal 6 layer and the via portion of the metal 7 layer, and lining the trenches with a thin conductor (such as first terminal 392), a thin insulator (such as dielectric 396), and another thin conductor (such as second terminal 394), the thin insulator insulating one thin conductor from the other thin conductor. The capacitor 390 is fabricated in a separate process from the rest of the metal 6 layer and metal 7 layer fabrication (to account for its large height and different electrode material from the rest of the metal 6 layer and metal 7 layer). This creates a relatively large capacitance in the capacitor 390 by having a relatively large surface area for the terminals (e.g., first and second terminals 392 and 394) separated by a relatively small amount of insulation (e.g., dielectric 396).

In further detail, in one or more embodiments of the present disclosure, the capacitor 390 is formed by etching a trench in the metal 6 layer (e.g., interconnect portion) and metal 7 layer (e.g., via portion), and successively filling the trench with the three layers by, for example, atomic level deposition (ALD). For instance, the first terminal 392 can be filled to a thickness of 20-40 nm using a conductive material (e.g., metal, conductive metal nitride or carbide, or the like), followed by a thin dielectric 396 (to increase capacitance, for example, 20-40 nm), followed by a second terminal 394 again, using metal (such as 20-40 nm thick), which can be coupled to the top electrode of every other capacitor 390 (e.g., in an array of eDRAM memory cells). The capacitor 390 can be at least 300 nm in some embodiments (e.g., for metal 5 layers on the order of 140 nm), to provide sufficient capacitance.

For example, in one embodiment, the first terminal 392 is tantalum (Ta). In another embodiment, the first terminal 392 is titanium nitride (TiN). In some embodiments, the first terminal 392 is titanium aluminum nitride (e.g., TiAlN, where the molar amount of titanium is at least that of aluminum). In another embodiment, the first terminal 392 is tantalum aluminum carbide (TaAlC). In another embodiment, the first terminal 392 is tantalum nitride (TaN). For example, in one embodiment, the second terminal 394 is TiN. For example, in one embodiment, the dielectric 396 is SiO₂. In some embodiments, such as to reduce tunneling (e.g., when the dielectric 396 is very thin), the dielectric 396 is a high-κ dielectric material such as zirconium dioxide (ZrO₂) or aluminum oxide (Al₂O₃).

Each first terminal 392 of the capacitor 390 connects to a corresponding storage node 380. The first terminals 392 of the capacitors 390 are electrically insulated from each other while the second terminals 394 of the capacitors 390 are electrically connected to each other through a (shared) capacitor plate at the top of the capacitors 390, e.g., located in the via portion of the metal 7 layer. There may be separate capacitor plates for separate arrays of capacitors 390. The capacitor plate may be coupled to a common voltage line (for example in the interconnect portion of the metal 7 layer) to supply a common voltage to all of the second terminals 394 through the capacitor plate.

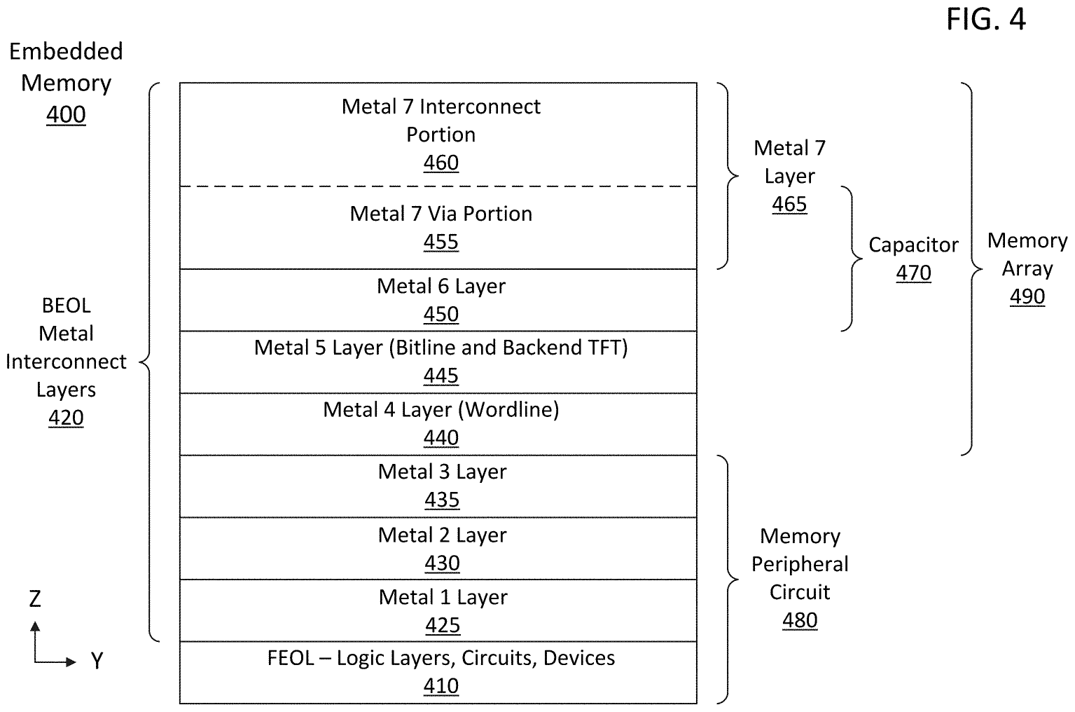

FIG. 4 is a cross-sectional (Y-Z) view of an example embedded memory 400, according to an embodiment of the present disclosure. FIG. 4 illustrates the Y and Z dimensions (width and height, respectively), the X dimension (length) extending into and out of the Y-Z plane. The embedded memory 400 includes an FEOL 410 that includes most of the various logic layers, circuits, and devices to drive and control the integrated circuit (e.g., chip) being fabricated with the embedded memory 400. As illustrated in FIG. 4, the embedded memory 400 also includes a BEOL 420 including, in this case, seven metal interconnection layers (namely, metal 1 layer 425, metal 2 layer 430, metal 3 layer 435, metal 4 layer 440, metal 5 layer 445, metal 6 layer 450, and metal 7 layer 465, including metal 7 via portion 455 and metal 7 interconnect portion 460) to interconnect the various inputs and outputs of the FEOL 410.

Generally speaking, and specifically illustrated for the metal 7 layer 465, each of the metal 1 layer 425 through the metal 7 layer 465 includes a via portion and an interconnect portion located above the via portion, the interconnect portion being for transferring signals along metal lines extending in the X or Y directions, the via portion being for transferring signals through metal vias extending in the Z direction (such as to the next lower metal layer underneath). Accordingly, vias connect metal structures (e.g., metal lines or vias) from one metal layer to metal structures of the next lower metal layer. Further, each of the metal 1 layer 425 through the metal 7 layer 465 includes a pattern of conductive metal, such as copper (Cu) or aluminum (Al), formed in a dielectric medium or interlayer dielectric (ILD), such as by photolithography.

In addition, the embedded memory 400 is further divided into a memory array 490 (e.g., an eDRAM memory array) built in the metal 4 layer 440 through the metal 7 layer 465 and including the backend TFTs (such as back-gated TFTs in the metal 5 layer 445) and capacitors 470 (in the metal 6 layer 450 and metal 7 layer via portion 455) as well as the wordlines (e.g., row selectors, in the metal 4 layer 440) and the bitlines (e.g., column selectors, in the metal 5 layer 445) making up the eDRAM memory cells, and a memory peripheral circuit 480 built in the FEOL and metal 1 layer 425 through metal 3 layer 435 to control (e.g., access, store, refresh) the memory array 490.

Compared to other techniques that locate such a memory control circuit in the same layers as the memory array but in a different macro (or X-Y) area of the integrated circuit than the memory array (such as at a periphery of the memory array), the embedded memory 400 locates the memory peripheral circuit 480 below the memory array 490 (e.g., in the same X-Y area). This saves valuable X-Y area in the finished integrated circuit. In further detail, the embedded memory 400 embeds the low-leakage selector TFTs (e.g., backend TFTs including back-gated TFTs) in the metal 5 layer 445 (such as the via portion of the metal 5 layer 445). For example, the metal 4 layer 440 can contain the wordlines extending in the X direction to select a row of memory cells (bits) while the metal 5 layer 445 can contain the bitlines extending in the Y direction to sense each of the memory cells (bits) in the selected row (and to write memory data to any of the memory cells in the selected row). The backend selector TFTs can be fabricated in the metal 5 layer 445, above the wordlines (that serve as or connect to the gate electrodes or contacts) and below the bitlines (that serve as the source electrodes or contacts). For example, the selector (back-gated) TFT can have the transistor gate below the thin-film layer (that can be formed at the bottom of the metal 5 layer 445, such as in the via portion) and source and drain contacts above the thin-film layer.

In further detail, in some embodiments, the metal gate of the back-gated TFT in each memory cell can be connected to a continuous metal 4 line below, such as a copper (Cu)-based metal line, which provides much lower resistance compared to gate lines formed in the lower (e.g., FEOL) portions of the integrated circuit. The continuous metal 4 line is used as the wordline of the memory array, and is covered by diffusion barriers or diffusion barrier layers including dielectric layers, such as silicon nitride (e.g., Si₃N₄), silicon carbide (e.g., SiC), or the like, with vias filled with metal-diffusion barrier films like tantalum nitride (TaN), tantalum (Ta), titanium zirconium nitride (e.g., Ti_{X}Zr_{1-X}N, such as X=0.53), titanium nitride (e.g., TiN), titanium tungsten (TiW), or the like. A metal gate layer covers the diffusion barrier film-filled vias, which electrically connect the copper (Cu) wordline to the metal gates of the selector TFTs, the diffusion barrier film preventing or helping to prevent the diffusion or migration of copper (Cu) from the wordline to the rest of the selector TFTs. The metal 5 layer 445 can include an active thin-film layer (e.g., indium gallium zinc oxide, or IGZO) and then source and drain contacts above the thin-film layer. The space between the source and drain contacts determines the gate length of the selector transistor. A three-dimensional capacitor 470 is embedded in the metal 6 layer 450 and via portion 455 of the metal 7 layer 465 (below the metal 7 interconnect portion 460).

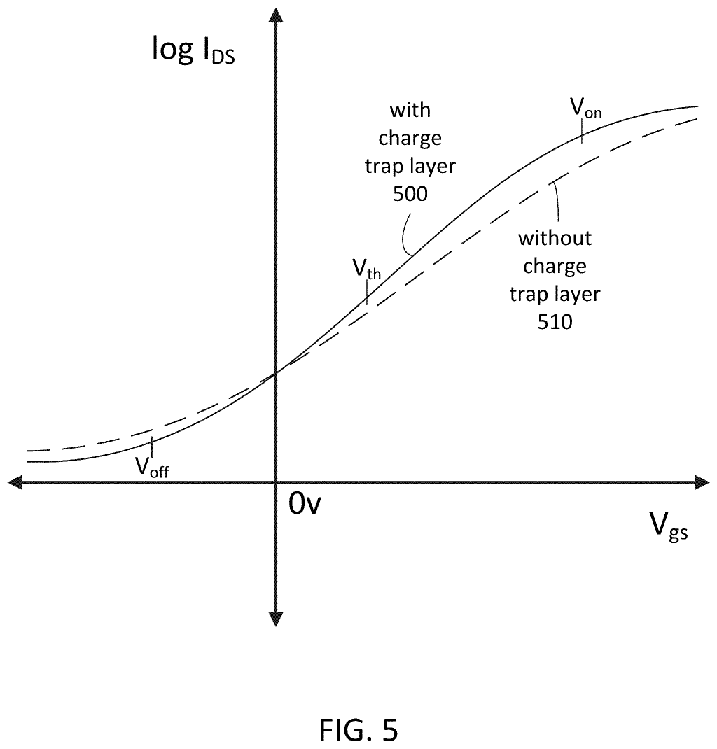

FIG. 5 is an example voltage-current curve 500 and comparison curve 510 for driving a back-gated TFT, according to an embodiment of the present disclosure. The curve 500 is representative of an embodiment of the present disclosure, the back-gated TFT having a charge trap layer as described above. The curve 510 is for a similar configuration, only no charge trap layer is present. The x-axis of FIG. 5 tracks the gate-to-source voltage V_{gs} of the TFT (increasing to the right, with 0 volts at the intersection with the y-axis), while the y-axis tracks the base 10 logarithm of the corresponding drain-to-source current I_{DS} corresponding to the gate voltage V_{gs}, the voltage increasing in an upward direction of the y-axis. Three different voltages are identified on the charge trap layer curve 500 (and exist in similar locations on the no charge trap layer curve 510): the gate off voltage V_{off} (e.g., the voltage at which the back-gated TFT is effectively off, such as when supplying minimal current), the gate on voltage Vₒₙ (e.g., the voltage at which the back-gated TFT is fully on, such as when supplying maximal current), and the threshold voltage Vₜₕ (e.g., the voltage at which the channel region between the source and drain regions becomes a conductive channel).

In FIG. 5, the charge trap layer curve 500 represents a voltage-current curve for an example embodiment of the present disclosure, while the curve 510 represents the voltage-current curve for the same configuration only without the charge trap layer. The subthreshold swing (SS) is the ratio of the x-axis (voltage) to the y-axis (current). As can be seen by comparing the two curves 500 and 510, the effect of removing the charge trap layer is to increase the SS, e.g., take more voltage to cause a similar increase in current. Increased SS leads to, for example, degraded TFT performance and a higher voltage device.

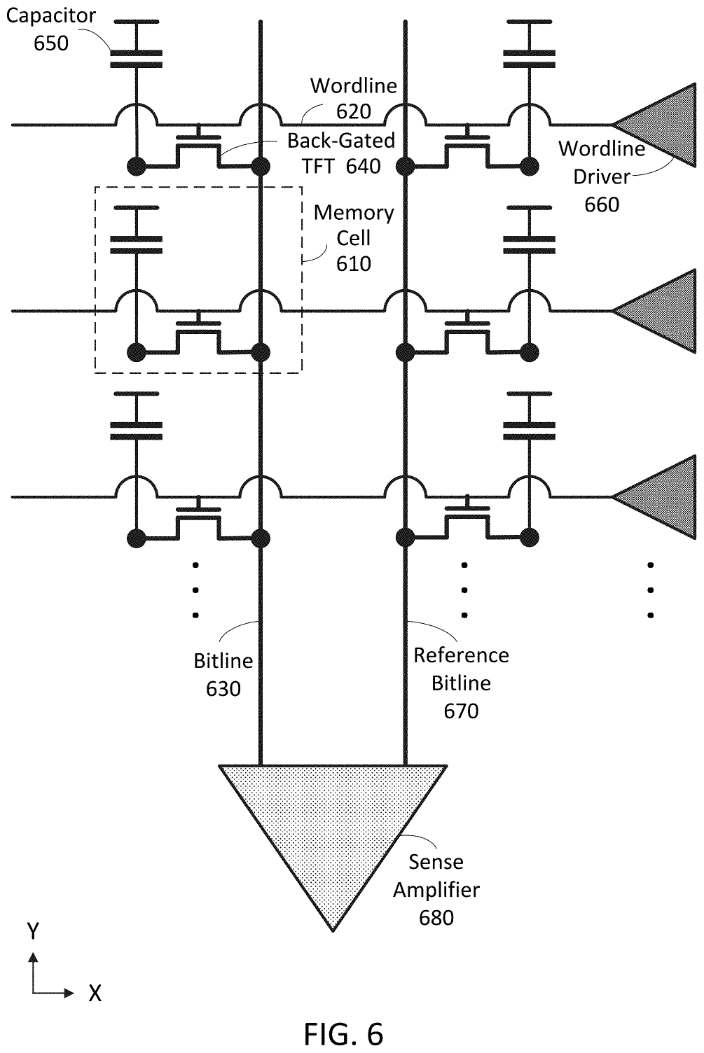

FIG. 6 is a schematic plan (X-Y) view of an example embedded memory configuration, according to an embodiment of the present disclosure. The memory array configuration of FIG. 6 includes memory cells 610 at crossing regions of wordlines 620 and bitlines 630 (e.g., each memory cell 610 being driven by a unique pair of wordline 620 and bitline 630), each memory cell 610 including a back-gated TFT 640 and a capacitor 650. Each wordline 620 is selected by a corresponding wordline driver 660, while the corresponding bitlines 630 are used to sense the state of the capacitor 650 (e.g., logical 1 or 0) of each of the corresponding bits of the selected wordline 620. In some embodiments, a reference column of memory cells provides a corresponding reference signal (e.g., halfway between a logic low value and a logic high value) over a reference bitline 670 concurrently with the sensing of the desired bit on the bitline 630. These two values are compared, by a sense amplifier 680, which determines whether the desired bit is a logic high value (e.g., 1) or a logic low value (e.g., 0).

The memory cells 610 are embedded in BEOL layers (such as the higher metal interconnect layers of the BEOL) while the peripheral circuits responsible for memory operation, including the read sense amplifiers 680 (and other bitline driver circuits) and wordline driver circuits 660, are placed below the memory array (e.g., in the FEOL and lower metal interconnect layers of the BEOL) to reduce area of the embedded memory.

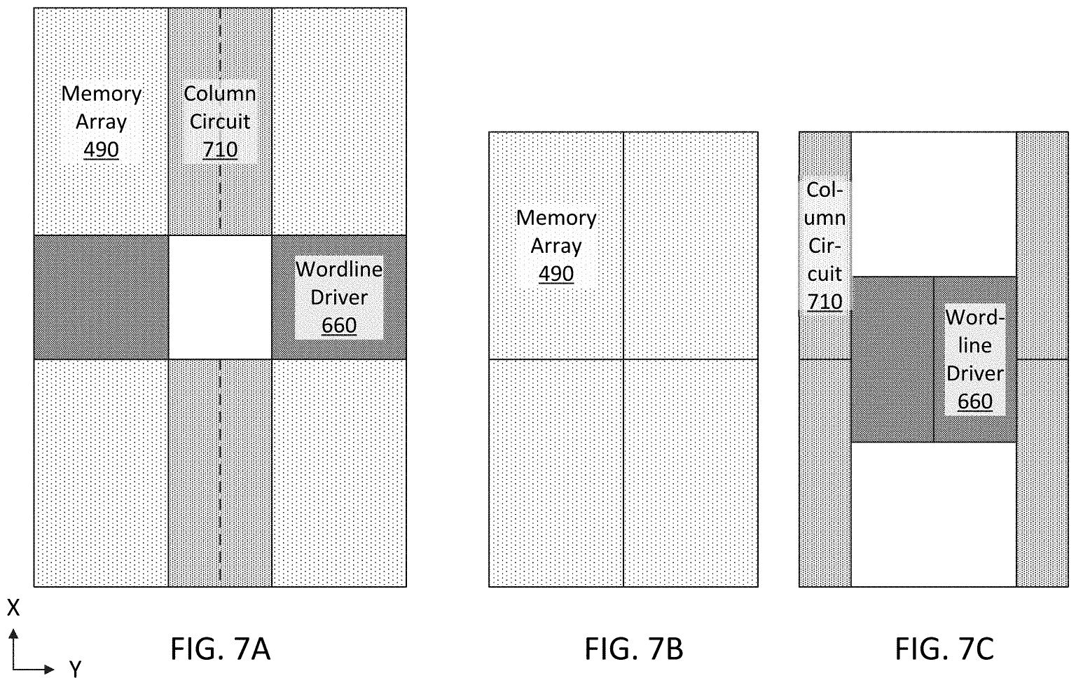

FIG. 7A is a plan (Y-X) view of an example layout of an embedded memory without overlap of the memory array 490 and memory peripheral circuit (illustrated as wordline drivers 660 and column circuits 710). FIGS. 7B-7C are plan (Y-X) views of an example layout or floorplan of an embedded memory with overlap of the memory array 490 and memory peripheral circuits 660 and 710, according to an embodiment of the present disclosure.

The column circuits 710 (or bitline drivers) include devices such as read (bitline) sense amplifiers 680 and precharging circuits. FIG. 7A shows the circuits spread out (e.g., occupying FEOL macro area or CMOS logic transistor area) and without overlap. By contrast, FIG. 7B shows the memory array 490 occupying the higher metal interconnection layers of the BEOL 420 (as illustrated in FIGS. 1-4 and 6) and FIG. 7C shows the memory peripheral circuits 660 and 710 occupying the FEOL 410 and lower metal interconnection layers of the BEOL 420 underneath the memory array 490 (as illustrated in FIG. 4). Since more than 35% of the embedded memory macro area can be consumed by the peripheral (memory control) circuits, substantial savings of X-Y macro area can be saved by fabricating the memory arrays above the memory peripheral circuits, as in one or more embodiments of the present disclosure. Put another way, according to some embodiments of the present disclosure, an embedded memory is provided with memory cells only using space in the upper metal layers (e.g., metal 4 layer and above), the peripheral circuits being moved below the memory cells (e.g., in metal 3 layer and below, including the FEOL) and substantially reduce the memory area.

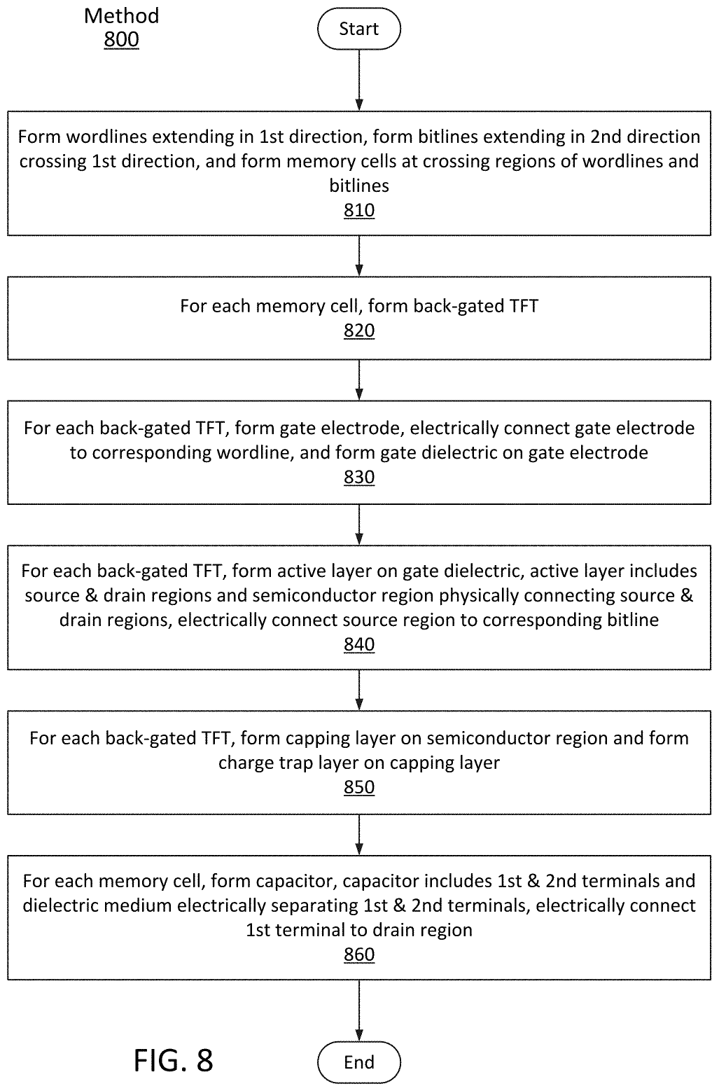

FIG. 8 illustrates an example method 800 of fabricating a back-gated TFT-based memory array (e.g., a DRAM array), according to an embodiment of the present disclosure. This and other methods disclosed herein may be carried out using integrated circuit fabrication techniques such as photolithography as would be apparent in light of the present disclosure. The corresponding memory cell and embedded memory including the memory cells may be part of other (logic) devices on the same substrate, such as application specific integrated circuits (ASICs), microprocessors, central processing units, processing cores, and the like. Unless otherwise described herein, verbs such as “coupled” or “couple” refer to an electrical coupling (such as capable of transmitting an electrical signal), either directly or indirectly (such as through one or more conductive layers in between).

Referring to FIG. 8 (with specific example references to the structures of FIGS. 1-4 and 6-7) method 800 includes forming 810 a plurality of wordlines (such as wordlines 620) extending in a first direction (such as an X-direction), forming a plurality of bitlines (such as bitlines 270 and 630) extending in a second direction (such as a Y-direction) crossing the first direction, and forming a plurality of memory cells (such as memory cells 200, 300, and 610) at crossing regions of the wordlines and the bitlines. For each memory cell, method 800 further includes forming 820 a back-gated TFT (such as back-gated TFTs 100 and 640). For each back-gated TFT, method 800 includes forming 830 a gate electrode (such as gate 120), electrically connecting the gate electrode to a corresponding one of the wordlines, and forming a gate dielectric (such as gate dielectric 130) on the gate electrode. For each back-gated TFT, method 800 further includes forming 840 an active layer (such as active layer 140) on the gate dielectric, the active layer including source and drain regions (such as source and drain regions 142 and 144) and a semiconductor region (such as channel region 146) physically connecting the source and drain regions, and electrically connecting the source region to a corresponding one of the bitlines. For each back-gated TFT, method 800 further includes forming 850 a capping layer (such as capping layer 170) on the semiconductor region and forming a charge trap layer (such as charge trap layer 180) on the capping layer. For each memory cell, method 800 further includes forming 860 a capacitor (such as capacitors 290, 390, 470, and 650) including first and second terminals (such as first and second terminals 292 and 294, as well as 392 and 394), and a dielectric medium (such as dielectric media 296 and 396) electrically separating the first and second terminals, and electrically connecting the first terminal to the drain region.

While the above example methods appear as a series of operations or stages, it is to be understood that there is no required order to the operations or stages unless specifically indicated. For example, in various embodiments of method 800, for each memory cell, the electrically connecting 840 of the one of the source region to a corresponding one of the bitlines can take place before, during, or after the forming 850 of the capping layer on the semiconductor region and the forming of the charge trap layer on the capping layer.

### Example System

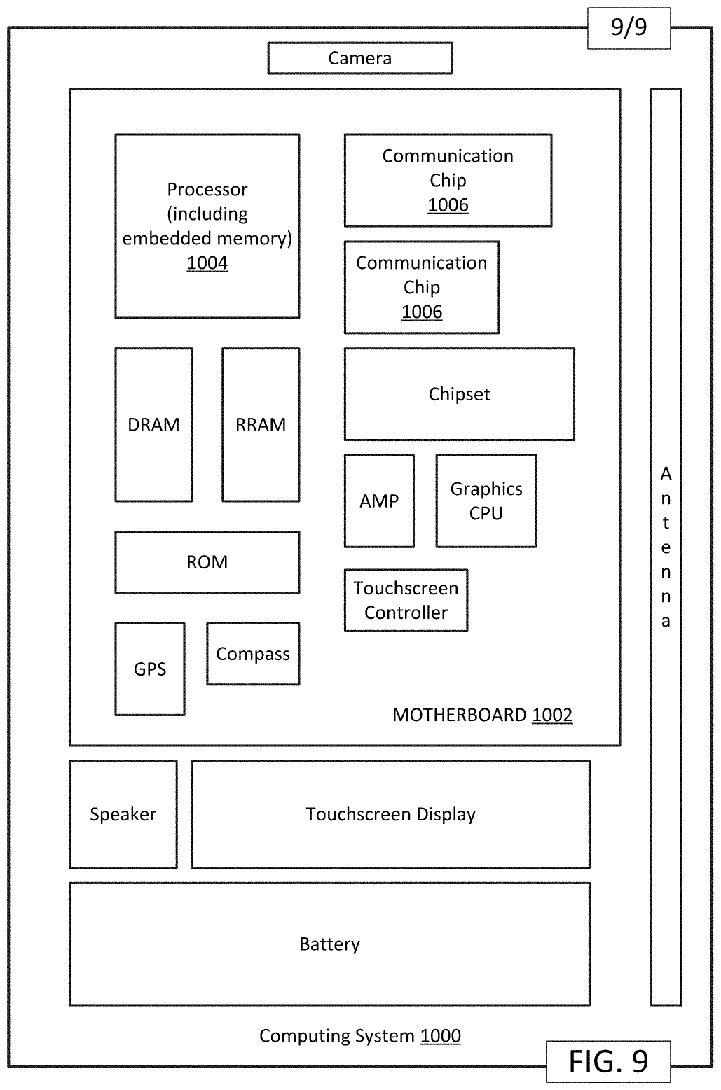

FIG. 9 illustrates a computing system 1000 implemented with the integrated circuit structures or techniques disclosed herein, according to an embodiment of the present disclosure. As can be seen, the computing system 1000 houses a motherboard 1002. The motherboard 1002 may include a number of components, including, but not limited to, a processor 1004 (including embedded memory) and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, to name a few examples.

Depending on its applications, computing system 1000 may include one or more other components that may or may not be physically and electrically coupled to the motherboard 1002. These other components may include, but are not limited to, volatile memory (e.g., DRAM), nonvolatile memory (e.g., read-only memory (ROM), resistive random-access memory (RRAM), and the like), a graphics processor, a digital signal processor, a crypto (or cryptographic) processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices (e.g., one or more memory cells) formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, and the like, that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices (e.g., one or more memory cells) formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices (e.g., one or more memory cells) formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices (e.g., one or more memory cells) formed using the disclosed techniques, as variously described herein.

### Further Example Embodiments

The following examples pertain to further embodiments, from which numerous permutations and configurations will be apparent.

Example 1 is a back-gated thin-film transistor (TFT) including: a gate electrode; a gate dielectric on the gate electrode; a first layer including a source region, a drain region, and a semiconductor region above and in direct contact with the gate dielectric and physically connecting the source and drain regions; a second layer including an insulator material on the semiconductor region; and a charge trap layer on the second layer.

Example 2 includes the back-gated TFT of Example 1, where the semiconductor region includes one or more of indium gallium zinc oxide (IGZO), indium zinc oxide (IZO), indium tin oxide (ITO), amorphous silicon (a-Si), zinc oxide, polysilicon, poly-germanium, low-temperature polycrystalline silicon (LTPS), amorphous germanium (a-Ge), indium arsenide, copper oxide, and tin oxide.

Example 3 includes the back-gated TFT of Example 2, where the semiconductor region includes one or more of IGZO, IZO, a-Si, LTPS, and a-Ge.

Example 4 includes the back-gated TFT of any of Examples 1-3, where the insulator material includes one or more of aluminum oxide, gallium oxide, silicon nitride, silicon dioxide, titanium dioxide, hafnium dioxide, silicon oxynitride, aluminum silicate, tantalum oxide, hafnium tantalum oxide, aluminum nitride, aluminum silicon nitride, sialon, zirconium dioxide, hafnium zirconium oxide, tantalum silicate, and hafnium silicate.

Example 5 includes the back-gated TFT of Example 4, where the insulator material includes one or more of aluminum oxide, silicon nitride, titanium dioxide, hafnium dioxide, silicon oxynitride, and aluminum nitride.

Example 6 includes the back-gated TFT of any of Examples 1-5, where the charge trap layer includes one or more of silicon nitride, tantalum oxide, titanium oxide, silicon oxynitride, hafnium dioxide, hafnium titanium oxide, hafnium tantalum oxide, aluminum nitride, aluminum oxynitride, silicon aluminum nitride, silicon:silicon dioxide, silicon:hafnium dioxide, silicon:silicon nitride, gallium oxide, and aluminum oxide.

Example 7 includes the back-gated TFT of Example 6, where the charge trap layer includes one or more of silicon nitride, silicon aluminum nitride, and silicon:silicon dioxide.

Example 8 includes the back-gated TFT of any of Examples 1-7, further including source and drain electrodes electrically connected to the source and drain regions, where the second layer physically connects and electrically separates the source and drain electrodes.

Example 9 includes the back-gated TFT of Example 8, where the charge trap layer physically connects and electrically separates the source and drain electrodes.

Example 10 includes the back-gated TFT of any of Examples 1-9, where the gate dielectric includes a high-κ dielectric.

Example 11 includes the back-gated TFT of Example 10, where the high-κ dielectric includes hafnium dioxide (HfO2).

Example 12 includes the back-gated TFT of Example 11, where the gate dielectric has a thickness between 2 and 10 nanometers (nm).

Example 13 is a memory cell including: the back-gated TFT of any of Examples 1-12, the gate electrode being electrically connected to a wordline and the source region being electrically connected to a bitline; and a capacitor including a first terminal electrically connected to the drain region, a second terminal, and a dielectric medium electrically separating the first and second terminals.

Example 14 is a memory array including a plurality of wordlines extending in a first direction, a plurality of bitlines extending in a second direction crossing the first direction, and a plurality of memory cells at crossing regions of the wordlines and the bitlines, the memory cells including a first memory cell and a second memory cell, each of the first and second memory cells having a structure of the memory cell of Example 13, with the wordline being a corresponding one of the wordlines and the bitline being a corresponding one of the bitlines.

Example 15 is a backend TFT including the back-gated TFT of any of Examples 1-12, the backend TFT being electrically connected to a frontend circuit.

Example 16 is an embedded memory cell including: the backend TFT of Example 15, the gate electrode being electrically connected to a wordline and the source region being electrically connected to a bitline; and a capacitor including a first terminal electrically connected to the drain region, a second terminal, and a dielectric medium electrically separating the first and second terminals.

Example 17 includes the embedded memory cell of Example 16, where the frontend circuit includes a wordline driver electrically connected to the wordline and a sense amplifier electrically connected to the bitline.

Example 18 is an embedded memory including a plurality of wordlines extending in a first direction, a plurality of bitlines extending in a second direction crossing the first direction, and a plurality of embedded memory cells at crossing regions of the wordlines and the bitlines, the embedded memory cells including a first embedded memory cell and a second embedded memory cell, each of the first and second embedded memory cells having a structure of the embedded memory cell of any of Examples 16-17, with the wordline being a corresponding one of the wordlines and the bitline being a corresponding one of the bitlines.

Example 19 includes the embedded memory of Example 18, where the frontend circuit includes a plurality of wordline drivers electrically connected to the wordlines and a plurality of sense amplifiers electrically connected to the bitlines.

Example 20 is a memory cell including: a back-gated thin-film transistor (TFT) including a gate electrode electrically connected to a wordline, a gate dielectric on the gate electrode, an active layer on the gate dielectric and having a source region, a drain region electrically connected to a bitline, and a semiconductor region physically connecting the source and drain regions, a capping layer on the semiconductor region, and a charge trap layer on the capping layer; and a capacitor including a first terminal electrically connected to the drain region, a second terminal, and a dielectric medium electrically separating the first and second terminals.

Example 21 includes the memory cell of Example 20, where the semiconductor region includes one or more of indium gallium zinc oxide (IGZO), indium zinc oxide (IZO), indium tin oxide (ITO), amorphous silicon (a-Si), zinc oxide, polysilicon, poly-germanium, low-temperature polycrystalline silicon (LTPS), amorphous germanium (a-Ge), indium arsenide, copper oxide, and tin oxide.

Example 22 includes the memory cell of Example 21, where the semiconductor region includes one or more of IGZO, IZO, a-Si, LTPS, and a-Ge.

Example 23 includes the memory cell of any of Examples 20-22, where the capping layer includes one or more of aluminum oxide, gallium oxide, silicon nitride, silicon dioxide, titanium dioxide, hafnium dioxide, silicon oxynitride, aluminum silicate, tantalum oxide, hafnium tantalum oxide, aluminum nitride, aluminum silicon nitride, sialon, zirconium dioxide, hafnium zirconium oxide, tantalum silicate, and hafnium silicate.

Example 24 includes the memory cell of Example 23, where the capping layer includes one or more of aluminum oxide, silicon nitride, titanium dioxide, hafnium dioxide, silicon oxynitride, and aluminum nitride.

Example 25 includes the memory cell of any of Examples 20-24, where the charge trap layer includes one or more of silicon nitride, tantalum oxide, titanium oxide, silicon oxynitride, hafnium dioxide, hafnium titanium oxide, hafnium tantalum oxide, aluminum nitride, aluminum oxynitride, silicon aluminum nitride, silicon:silicon dioxide, silicon:hafnium dioxide, silicon:silicon nitride, gallium oxide, and aluminum oxide.

Example 26 includes the memory cell of Example 25, where the charge trap layer includes one or more of silicon nitride, silicon aluminum nitride, and silicon:silicon dioxide.

Example 27 includes the memory cell of any of Examples 20-26, further including source and drain electrodes electrically connected to the source and drain regions, where the capping layer physically connects and electrically separates the source and drain electrodes.

Example 28 includes the memory cell of Example 27, where the charge trap layer physically connects and electrically separates the source and drain electrodes.

Example 29 includes the memory cell of any of Examples 20-28, where the gate dielectric includes a high-κ dielectric.

Example 30 includes the memory cell of Example 29, where the high-κ dielectric includes hafnium dioxide (HfO2).

Example 31 includes the memory cell of Example 30, where the gate dielectric has a thickness between 2 and 10 nanometers (nm).

Example 32 is a memory array including a plurality of wordlines extending in a first direction, a plurality of bitlines extending in a second direction crossing the first direction, and a plurality of memory cells at crossing regions of the wordlines and the bitlines, the memory cells including a first memory cell and a second memory cell, each of the first and second memory cells having a structure of the memory cell of any of Examples 20-31, with the wordline being a corresponding one of the wordlines and the bitline being a corresponding one of the bitlines.

Example 33 is an embedded memory cell including the memory cell of any of Examples 20-31, the back-gated TFT being a backend TFT electrically connected to a frontend circuit, the frontend circuit including a wordline driver electrically connected to the wordline and a sense amplifier electrically connected to the bitline.

Example 34 is an embedded memory including a plurality of wordlines extending in a first direction, a plurality of bitlines extending in a second direction crossing the first direction, and a plurality of embedded memory cells at crossing regions of the wordlines and the bitlines, the embedded memory cells including a first embedded memory cell and a second embedded memory cell, each of the first and second embedded memory cells having a structure of the embedded memory cell of Example 33, with the wordline being a corresponding one of the wordlines and the bitline being a corresponding one of the bitlines.

Example 35 includes the embedded memory of Example 34, where the frontend circuit further includes a plurality of wordline drivers electrically connected to the wordlines, and a plurality of sense amplifiers electrically connected to the bitlines.

Example 36 is a method of fabricating a back-gated thin-film transistor (TFT), the method including: forming a gate electrode; forming a gate dielectric on the gate electrode; forming a first layer including a source region, a drain region, and a semiconductor region above and in direct contact with the gate dielectric and physically connecting the source and drain regions; forming a second layer including an insulator material on the semiconductor region; and forming a charge trap layer on the second layer.

Example 37 includes the method of Example 36, where the semiconductor region includes one or more of indium gallium zinc oxide (IGZO), indium zinc oxide (IZO), indium tin oxide (ITO), amorphous silicon (a-Si), zinc oxide, polysilicon, poly-germanium, low-temperature polycrystalline silicon (LTPS), amorphous germanium (a-Ge), indium arsenide, copper oxide, and tin oxide.

Example 38 includes the method of Example 37, where the semiconductor region includes one or more of IGZO, IZO, a-Si, LTPS, and a-Ge.

Example 39 includes the method of any of Examples 36-38, where the insulator material includes one or more of aluminum oxide, gallium oxide, silicon nitride, silicon dioxide, titanium dioxide, hafnium dioxide, silicon oxynitride, aluminum silicate, tantalum oxide, hafnium tantalum oxide, aluminum nitride, aluminum silicon nitride, sialon, zirconium dioxide, hafnium zirconium oxide, tantalum silicate, and hafnium silicate.

Example 40 includes the method of Example 39, where the insulator material includes one or more of aluminum oxide, silicon nitride, titanium dioxide, hafnium dioxide, silicon oxynitride, and aluminum nitride.

Example 41 includes the method of any of Examples 36-40, where the charge trap layer includes one or more of silicon nitride, tantalum oxide, titanium oxide, silicon oxynitride, hafnium dioxide, hafnium titanium oxide, hafnium tantalum oxide, aluminum nitride, aluminum oxynitride, silicon aluminum nitride, silicon:silicon dioxide, silicon:hafnium dioxide, silicon:silicon nitride, gallium oxide, and aluminum oxide.

Example 42 includes the method of Example 41, where the charge trap layer includes one or more of silicon nitride, silicon aluminum nitride, and silicon:silicon dioxide.

Example 43 includes the method of any of Examples 36-42, where the forming of the charge trap layer includes forming an oxide or nitride on the second layer and doping the formed oxide or nitride.

Example 44 includes the method of Example 43, where the doping of the formed oxide or nitride includes doping the formed oxide or nitride with impurities having the same polarity as majority carriers of the semiconductor region.

Example 45 includes the method of any of Examples 36-44, further including forming source and drain electrodes electrically connected to the source and drain regions, where the second layer physically connects and electrically separates the source and drain electrodes.

Example 46 includes the method of Example 45, where the charge trap layer physically connects and electrically separates the source and drain electrodes.

Example 47 includes the method of any of Examples 36-46, where the gate dielectric includes a high-κ dielectric.

Example 48 includes the method of Example 47, where the high-κ dielectric includes hafnium dioxide (HfO2).

Example 49 includes the method of Example 48, where the gate dielectric has a thickness between 2 and 10 nanometers (nm).

Example 50 is a method of fabricating a memory cell, the method including: fabricating the back-gated TFT by the method of any of Examples 36-49; electrically connecting the gate electrode to a wordline; electrically connecting the source region being to a bitline; forming a capacitor including first and second terminals, and a dielectric medium electrically separating the first and second terminals; and electrically connecting the first terminal to the drain region. Example 51 is a method of fabricating a memory array, the method including: forming a plurality of wordlines extending in a first direction; forming a plurality of bitlines extending in a second direction crossing the first direction; and forming a plurality of memory cells at crossing regions of the wordlines and the bitlines, the memory cells including a first memory cell and a second memory cell, each of the first and second memory cells being fabricated by the method of Example 50, with the wordline being a corresponding one of the wordlines and the bitline being a corresponding one of the bitlines.

Example 52 is a method of fabricating a backend TFT, the method including: fabricating the back-gated TFT by the method of any of Examples 36-49; and electrically connecting the backend TFT to a frontend circuit.

Example 53 is a method of fabricating an embedded memory cell, the method including: fabricating the backend TFT by the method of Example 52; electrically connecting the gate electrode to a wordline; and electrically connecting the source region to a bitline; forming a capacitor including first and second terminals, a second terminal, and a dielectric medium electrically separating the first and second terminals; and electrically connecting the first terminal to the drain region.

Example 54 includes the method of Example 53, where the frontend circuit includes a wordline driver and a sense amplifier, and the method further includes electrically connecting the wordline driver to the wordline and the sense amplifier to the bitline.

Example 55 is a method of fabricating an embedded memory, the method including: forming a plurality of wordlines extending in a first direction; forming a plurality of bitlines extending in a second direction crossing the first direction; and forming a plurality of embedded memory cells at crossing regions of the wordlines and the bitlines, the embedded memory cells including a first embedded memory cell and a second embedded memory cell, each of the first and second embedded memory cells being fabricated by the method of any of Examples 53-54, with the wordline being a corresponding one of the wordlines and the bitline being a corresponding one of the bitlines.

Example 56 includes the method of Example 55, where the frontend circuit includes a plurality of wordline drivers and a plurality of sense amplifiers, and the method further includes electrically connecting the wordline drivers to the wordlines and the sense amplifiers to the bitlines.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1-25. (canceled)

26. A back-gated thin-film transistor (TFT) comprising:
a gate electrode;
a gate dielectric on the gate electrode;
a first layer including a source region, a drain region, and a region above and in direct contact with the gate dielectric and physically connecting the source and drain regions, the region comprising semiconductor material;
a second layer comprising an insulator material on the region; and
a charge trap layer on the second layer.

27. The back-gated TFT of claim 26, wherein the region comprises one or more of indium, gallium, zinc, tin, arsenic, copper, oxygen, amorphous silicon (a-Si), polysilicon, poly-germanium, low-temperature polycrystalline silicon (LTPS), and amorphous germanium (a-Ge).

28. The back-gated TFT of claim 27, wherein the region comprises one or more of indium zinc oxide (IGZO), indium zinc oxide (IZO), a-Si, LTPS, and a-Ge.

29. The back-gated TFT of claim 26, wherein the insulator material comprises one or more of aluminum, gallium, silicon, titanium, hafnium, aluminum, tantalum, sialon, zirconium, oxygen, and nitrogen.

30. The back-gated TFT of claim 29, wherein the insulator material comprises one or more of aluminum oxide, silicon nitride, titanium dioxide, hafnium dioxide, silicon oxynitride, and aluminum nitride.

31. The back-gated TFT of claim 26, wherein the charge trap layer comprises one or more of silicon, tantalum, titanium, silicon, hafnium, hafnium, aluminum, silicon, gallium, oxygen, or nitrogen.

32. The back-gated TFT of claim 31, wherein the charge trap layer comprises one or more of silicon nitride, silicon aluminum nitride, and silicon:silicon dioxide.

33. The back-gated TFT of claim 26, further comprising source and drain electrodes electrically connected to the source and drain regions, wherein the second layer physically connects and electrically separates the source and drain electrodes.

34. The back-gated TFT of claim 33, wherein the charge trap layer physically connects and electrically separates the source and drain electrodes.

35. The back-gated TFT of claim 26, wherein the gate dielectric comprises a high-κ dielectric.

36. The back-gated TFT of claim 35, wherein the high-κ dielectric comprises hafnium dioxide (HfO₂).

37. The back-gated TFT of claim 36, wherein the gate dielectric has a thickness between 2 and 10 nanometers (nm).

38. A memory cell comprising:
the back-gated TFT of claim 26, the gate electrode being electrically connected to a wordline and the source region being electrically connected to a bitline; and
a capacitor including a first terminal electrically connected to the drain region, a second terminal, and a dielectric medium electrically separating the first and second terminals.

39. An embedded memory comprising a plurality of wordlines extending in a first direction and including a first wordline and a second wordline, a plurality of bitlines extending in a second direction and including a first bitline and a second bitline, a first memory cell at a first crossing region of the first wordline and the first bitline, and a second memory cell at a second crossing region of the second wordline and the second bitline, each of the first and second memory cells having a structure of the embedded memory cell of claim 38.

40. A backend TFT comprising the back-gated TFT of claim 26, the backend TFT being electrically connected to a frontend circuit.

41. An embedded memory cell comprising:
the backend TFT of claim 40, the gate electrode being electrically connected to a wordline and the source region being electrically connected to a bitline; and
a capacitor including a first terminal electrically connected to the drain region, a second terminal, and a dielectric medium electrically separating the first and second terminals,
wherein the frontend circuit comprises a wordline driver electrically connected to the wordline and a sense amplifier electrically connected to the bitline.

42. An embedded memory comprising a plurality of wordlines extending in a first direction and including a first wordline and a second wordline, a plurality of bitlines extending in a second direction and including a first bitline and a second bitline, a first memory cell at a first crossing region of the first wordline and the first bitline, and a second memory cell at a second crossing region of the second wordline and the second bitline, each of the first and second memory cells having a structure of the embedded memory cell of claim 41.

43. The embedded memory of claim 42, wherein the frontend circuit comprises a plurality of wordline drivers electrically connected to the wordlines and a plurality of sense amplifiers electrically connected to the bitlines.

44. A memory cell comprising:
a back-gated thin-film transistor (TFT) including
a gate electrode electrically connected to a wordline,
a gate dielectric on the gate electrode,
a first layer on the gate dielectric and having a source region, a drain region electrically connected to a bitline, and a region physically connecting the source and drain regions, the region comprising semiconductor material,
a source electrode electrically connected to the source region, and a drain electrode electrically connected to the drain region;
a second layer on the first layer and physically connecting and electrically separating the source and drain electrodes, and
a third layer on the second layer and physically connecting and electrically separating the source and drain electrodes, the third layer including a dopant; and
a capacitor including a first terminal electrically connected to the drain region, a second terminal, and a dielectric medium electrically separating the first and second terminals.

45. The memory cell of claim 44, wherein the third layer comprises one or more of silicon, tantalum, titanium, hafnium, aluminum, gallium, oxygen, and nitrogen.
